(19) United States
(12) Patent Application Publication
(10) Pub. No.: US 2012/0320546 A1
(43) Pub. Date: Dec. 20, 2012

(54) Single-Pull Multi-Function Device for Conveying Signal and/or Supplying Power

(76) Inventor: SUNG-CHIANG WU, New Taipei City (TW)

(21) Appl. No.: 13/163,731

(22) Filed: Jun. 20, 2011

(51) Int. Cl. H05K 7/00

(52) U.S. Cl. 361/755

(57) ABSTRACT

A single-pull multi-function device for conveying signal and/or supplying power comprises a housing, a power converting assembly, a reel assembly, an elastic member, an electrical module, and a cable. The power converting assembly includes a power converting module, an electrical port, and a power plug for external power connection. The reel assembly includes a reel rotatably mounted with a central axle of the housing. The reel defines a cylindrical recess being coaxially therewith. The elastic member, which is disposed in the cylindrical recess of the reel, has one end connected to the central axle of the housing and another end connected to the reel. The electrical module includes electrical ports and a circuit board mounted on the reel. The cable, which is wound along the reel, is electrically connected to the electrical module at one end thereof and is electrically connected to a connecting port assembly at another end thereof.

### TECHNICAL FIELD OF THE INVENTION

The present invention relates to a multi-function device for conveying signal and/or supplying power, and more particularly to a device that can obtain electrical power from various sources to supply mobile devices with suitable power for charging batteries thereof, or can serve as an extension cable for conveying signal between devices.

### DESCRIPTION OF THE PRIOR ART

Power supply is an important design that may influence the availability of mobile devices In general, conventional chargers lacks versatile connectors so that users should purchase additional adapters for various devices, and this may bring inconvenience in using the mobile devices. Also, conventional chargers can only provide the function of supplying electrical power and cannot serve as a medium for conveying signal between devices.

Thus, there is a need for a further improvement of conventional chargers to allow devices with various interfaces to be charged more easily from various sources. Also, the improved device can provide a function of signal communication for devices. After a constant efforts on the innovations of power supply devices, the applicant has contrive a device that can provide various ways of supplying electrical power or serve as an extension cable for providing communication between devices.

### SUMMARY OF THE INVENTION

The primary object of the present invention is to provide a multi-function device that can obtain electrical power from various sources to supply mobile devices with suitable power for charging batteries thereof.

Another object of the present invention is to provide a multi-function device that can serve as an extension cable for conveying signal between devices.

According to one primary feature of the present invention, the multi-function device comprising a housing, a power converting assembly, a reel assembly, an elastic member, an electrical module, and a cable.

The housing includes an upper cover, a base seat, and a lower cover, in which the upper cover and the lower cover are mounted to the base seat respectively at two sides of the base seat. The base seat is provided with a central axel and defines a cutout for cable exit and a cutout for accessing port. A tongue is pivotally mounted in the base seat. The upper cover defines at least one opening. The lower cover defines one or more slotted hole.

The power converting assembly, which is mounted in the housing, includes a power converting module, an electrical port fitted at a location corresponding to the cutout for accessing port, and a power plug fitted at a location corresponding to the slotted hole, through which the power plug can extend for external power connection.

The reel assembly, which is mounted in the housing, includes a reel rotatably mounted with the central axle of the base seat via a through hole thereof. The reel defines an annular groove along a circumference thereof and is provided with rails at a side thereof to cooperate with the tongue. The reel defines a cylindrical recess being coaxially therewith.

The elastic member, which is disposed in the cylindrical recess of the reel, has one end connected to the central axle of the base seat and another end connected to the reel.

The electrical module includes at least one electrical port and a circuit board mounted on the reel, the electrical port of the electrical module being accessible through the opening of the upper cover.

The cable, which is wound along the annular groove of the reel, is electrically connected to the electrical module at one end thereof and is electrically connected to a connecting port assembly, through the cutout for cable exit defined on the base seat, at another end thereof.

According to a second feature of the present invention, the multi-function device further comprises a protective cap mounted on the reel below the upper cover to be rotated together with the reel, the protective cap defining at least one slot at a portion being mated with the opening of the upper cover, the electrical port of the electrical module extending through the slot of the protective cap.

According to a third feature of the present invention, the multi-function device further comprising an adapting cable connected to the electrical port of the power converting assembly at one end thereof and connected to the electrical port of the electrical module at another end thereof so that the power converting assembly is electrically connected with the electrical module.

According to a fourth feature of the present invention, the multi-function device further comprising two rolling means being mounted in the housing near the cutout for cable exit, the cable extending out of the housing through a gap between the two rolling means so as to facilitate pulling the cable.

According to a fifth feature of the present invention, the multi-function device further comprising a partition plate being mounted on the reel between the electrical module and the elastic member for separating the electrical module from the elastic member to prevent friction therebetween.

According to a sixth feature of the present invention, the power plug of the power converting assembly includes a plug base mounted and electrically connected with the electrical module and two blades pivotably mounted on the plug base so that the power plug can be folded along the slotted hole.

According to a seventh feature of the present invention, the upper cover is mounted to the base seat by at least one fastening member.

According to an eighth feature of the present invention, the electrical port of the electrical module is adapted to connect to a cigarette lighter for cars or a USB port.

According to an ninth feature of the present invention, the connecting port assembly, the electrical port of the electrical module, the electrical port of the power converting assembly, or two ends of the adapting cable is adapted to connect to a USB connector, a MINI USB connector, a MICRO USB connector, an HDMI connector, or a tablet computer charging connector.

Other objects, advantages, and novel features of the present invention will become more apparent from the following detailed description when taken in conjunction with the accompanying drawings.

### BRIEF DESCRIPTION OF THE DRAWINGS

FIG. 1 schematically shows a 3-dimensional view of the present invention.

FIG. 2 is a first partially exploded view of the present invention, which shows the components covered by the upper cover.

FIG. 3 is a second partially exploded view of the present invention, which shows the components covered by the upper cover.

FIG. 4 is a third partially exploded view of the present invention, which shows the components covered by the upper cover.

FIG. 5 is a fourth partially exploded view of the present invention, which shows the components covered by the upper cover.

FIG. 6 is a fifth partially exploded view of the present invention, which shows the components covered by the upper cover.

FIG. 7 is a sixth partially exploded view of the present invention, which shows the components covered by the upper cover.

FIG. 8 is a partially exploded view of the present invention, which shows the components covered by the lower cover.

FIG. 9 is a schematic view of the present invention, which shows the components in the housing related to the lower cover.

FIG. 10 is a 3-dimensional view of the present invention viewed from the bottom, in which the power plug is extended out of the housing.

FIG. 11 is a 3-dimensional view of the present invention viewed from the bottom, in which the power plug is folded.

FIG. 12 is a 3-dimensional view of the present invention, in which the cable is pulled out of the housing.

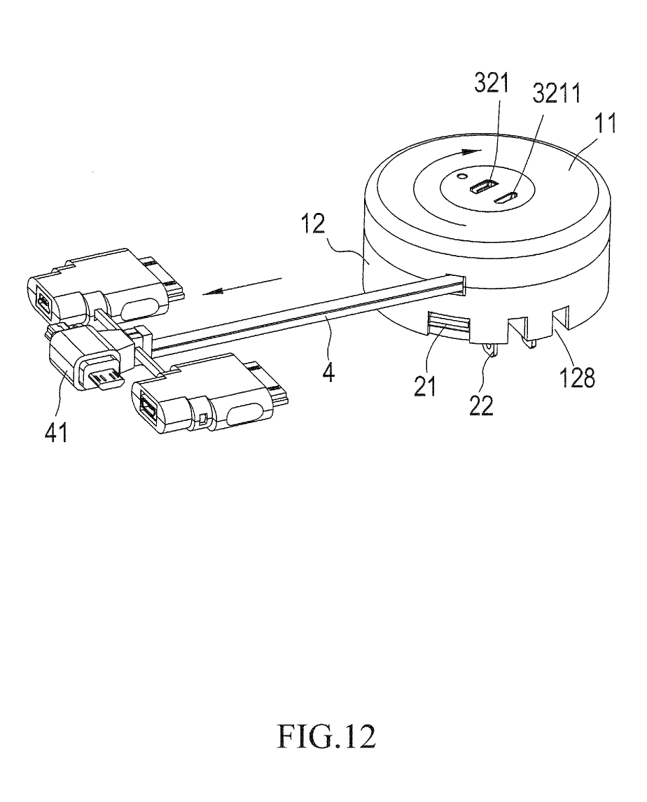

FIG. 13 is a 3-dimensional view of the present invention, which schematically shows a connection of the adapting cable.

FIG. 14 is a 3-dimensional view of the present invention, which schematically shows another connection of the adapting cable.

FIG. 15 is a 3-dimensional view of the present invention, which schematically shows another connection of the adapting cable for use with a cigarette lighter for cars.

FIG. 16 is a 3-dimensional view of the present invention, which schematically shows another connection of the adapting cable for use with a notebook computer.

### DETAILED DESCRIPTION OF THE PREFERRED EMBODIMENTS

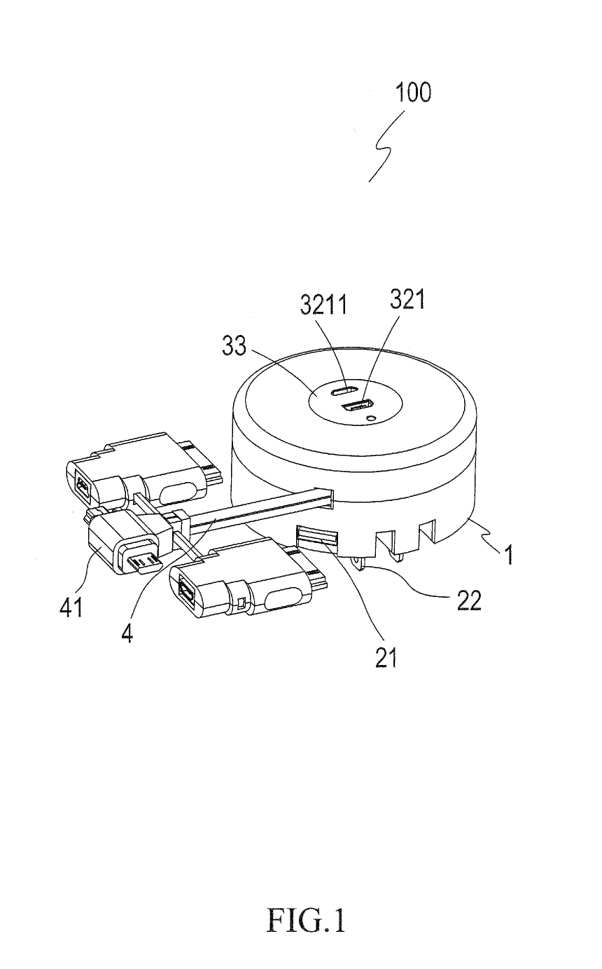

Referring to FIG. 1, a single-pull multi-function device for conveying signal and/or supplying power according to the present invention generally comprises a housing 1, a connecting port assembly 41, an electrical port 21 in a lower portion of the housing, and an electrical port 321 in an upper portion of the housing.

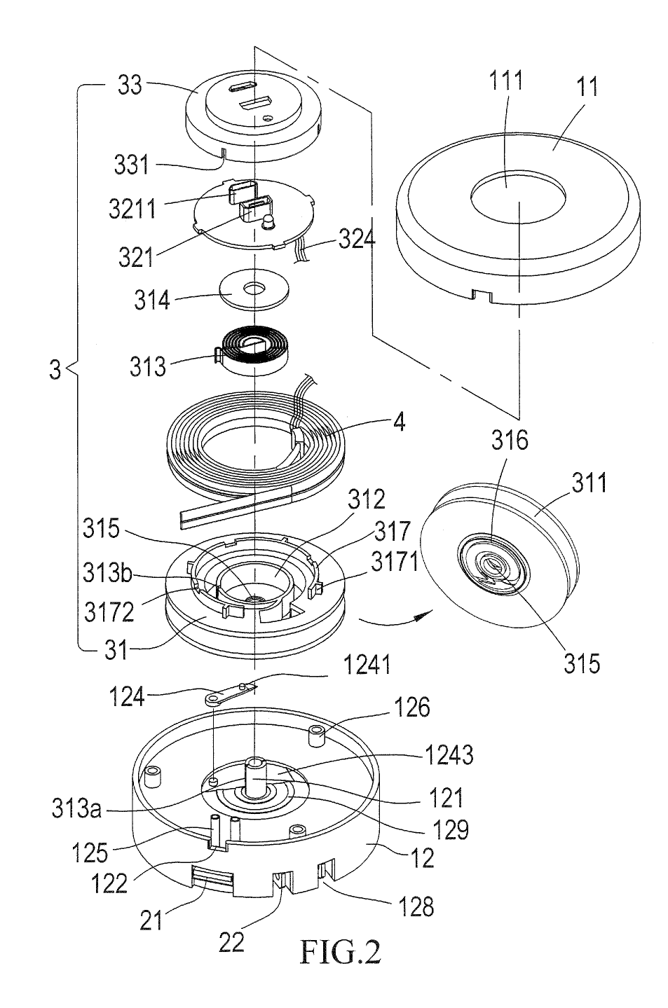

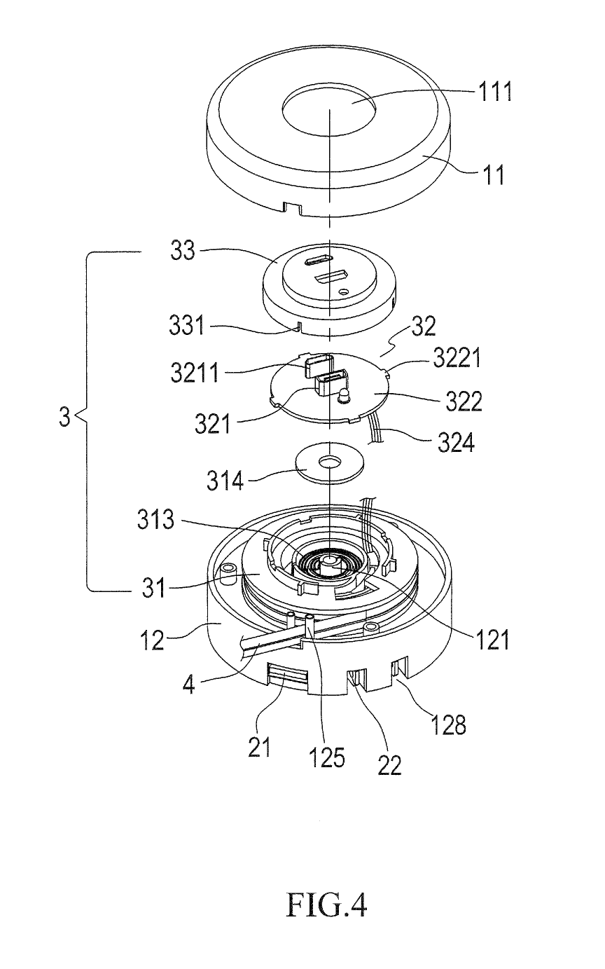

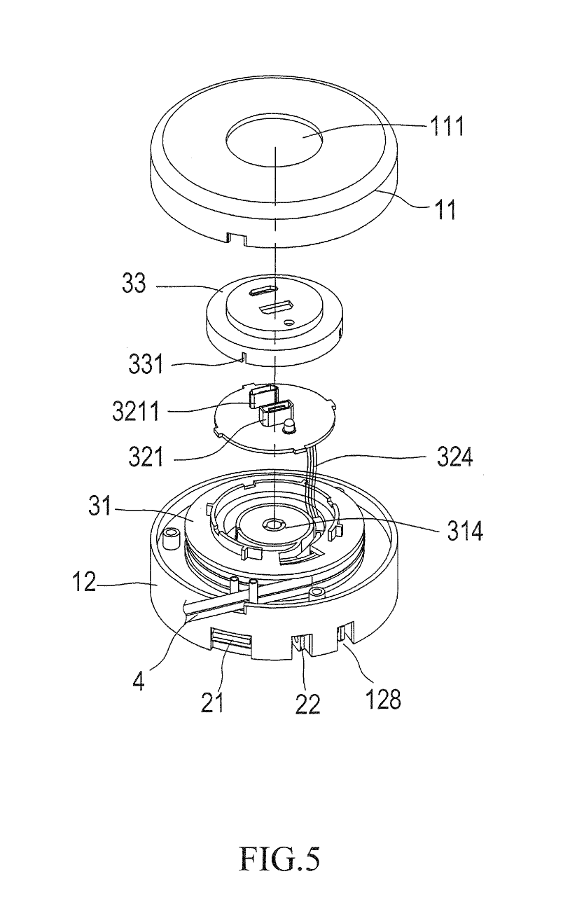

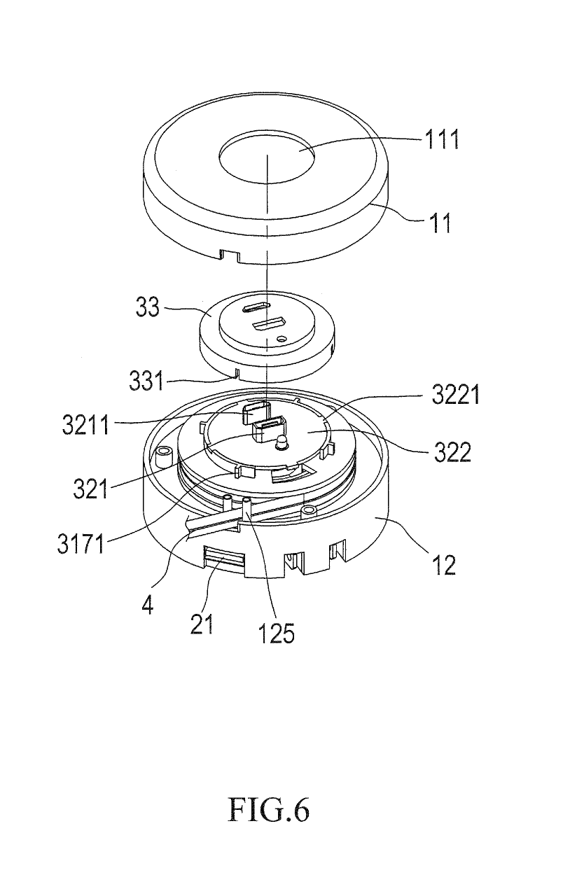

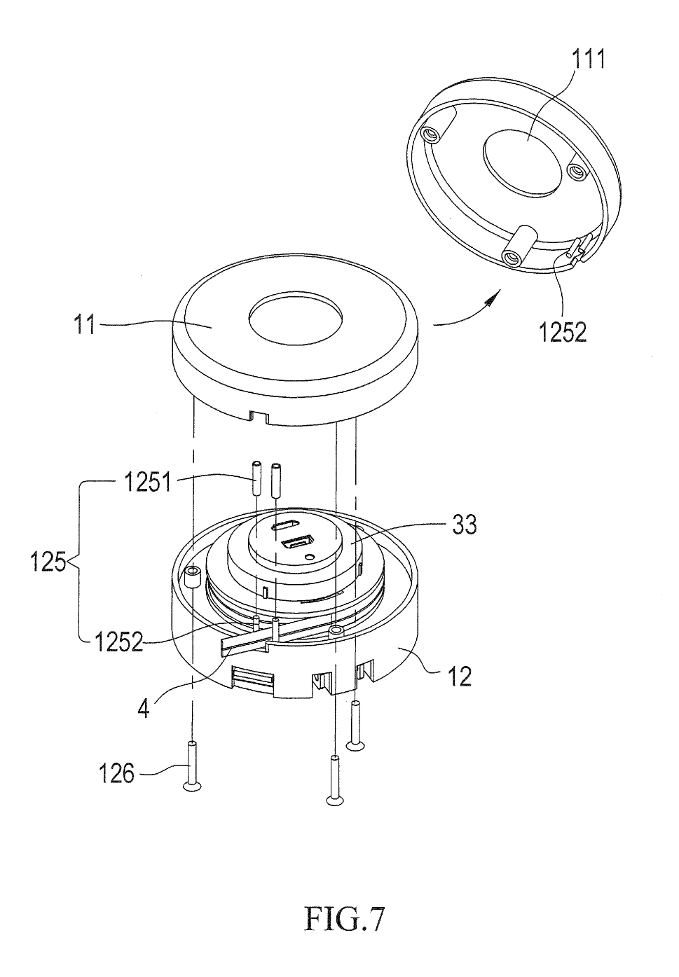

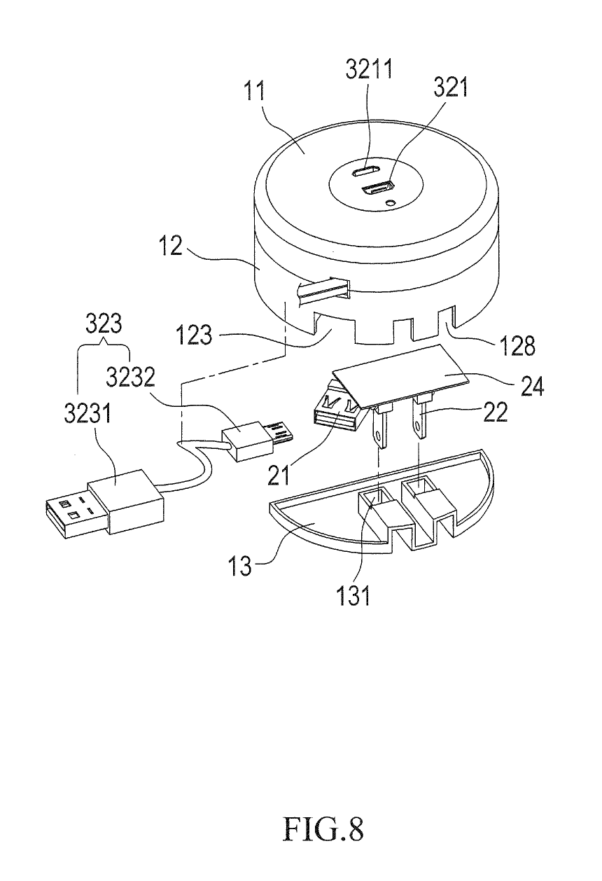

FIGS. 2-7 shows a partial number of components of the present invention. The housing 1 includes a base seat 12, an upper cover 11, and a lower cover 13 (see FIG. 8). As shown, the components in the base seat 12 covered by the upper cover 11 generally include a reel assembly 3 and a cable 4. In the base seat 12 is provided at least one fastening member 126 for fastening the upper cover 11 to the base seat 12.

The reel assembly 3 includes a reel 31, which defines an annular groove 311 along a circumference thereof for accommodating the cable 4 and a cylindrical recess 312 being coaxially therewith. A cylindrical wall 317, which is formed on the reel 31 around the cylindrical recess 312, defines a plurality of notches 3172 thereon and is provided with a plurality of fins 3171 on an outer surface thereof. The reel 31 defines a through hole 315 at a center thereof, through which a central axle 121 of the base seat 12 can insert so that the reel 31 is rotatably mounted with the base seat 12. The base seat 12 is provided with auxiliary rails 129 around the central axle 121, and a recessed sector 1243, on which a tongue 124 is pivotally mounted. The tongue 124, being provided with a boss 1241, can swing in the recessed sector 1243. The reel 31 is provided with rails 316 corresponding to the rails 129 of the base seat 12 and the boss 1241 of the tongue 124, so that the reel 31 can cooperate with the base seat 12.

In the cylindrical recess 312, an elastic member 313, such as a helical spring as shown in the embodiment, is disposed. The elastic member 313 has one end connected to the central axle 121 of the base seat 12 via a slit 313a and another end connected to the reel 31 via a slit 313b. In such arrangement, the elastic member 313 can provide a restoring force for retracting the cable 4 into the housing 1. A partition plate 314 is mounted on the reel 31, between an electrical module 32 and the elastic member 313. The electrical module 32 includes electrical ports 321, 3211 and a circuit board 322 mounted on the reel 31. The electrical ports 321, 3211, which can be a USB connector, are electrically connected via the circuit board 322. The electrical module 32 is provided with a plurality of projections 3221 along a circumference thereof for engaging with the notches 3172 of the cylindrical wall 317 so as to mount with the reel 31.

A protective cap 33 is placed between the electrical module 32 and the upper cover 11. The protective cap 33, which is mounted on the reel 31 below the upper cover 11, has a cylindrical portion for being mated with an opening 111 of the upper cover 11. The protective cap 33 defines a plurality of slits 331 on a circumference thereof for engaging with the fins 3171 of the cylindrical wall 317 of the reel 31 so that the protective cap 33 can be rotated together with the reel 31.

Two parallel rolling means 125 are mounted in the base seat 12 near the cutout 122 for cable exit. Each rolling means 125 includes a rolling cylinder 1251 rotatably fitted around two pins 1252 respectively fixed on the base seat 12 and the upper cover 11. The cable 4 is guided through a gap between the two rolling means 125 and then directed through the cutout 122. In such arrangement, the cable 4 can be pulled out of the housing to keep clear of the edges around the cutout 122 so that the cable 4 can be smoothly pulled out of the housing.

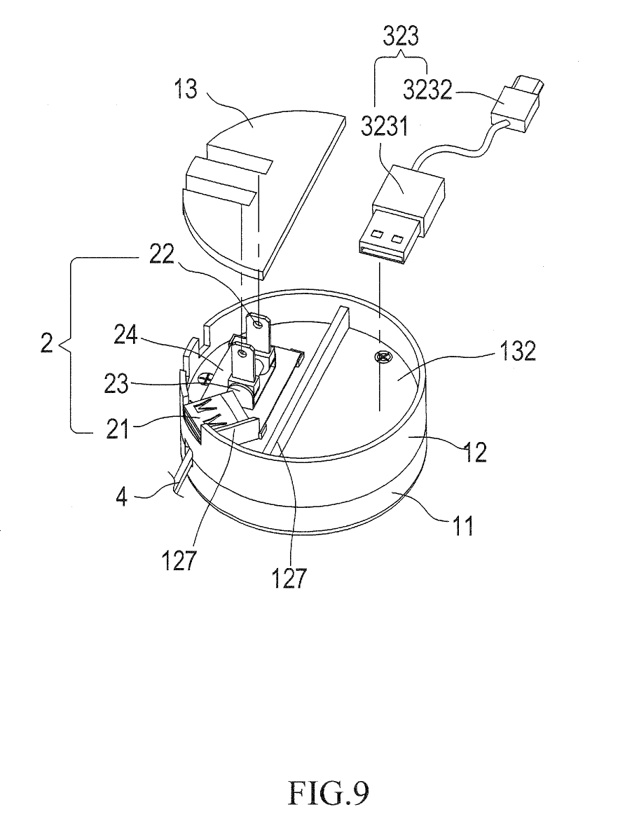

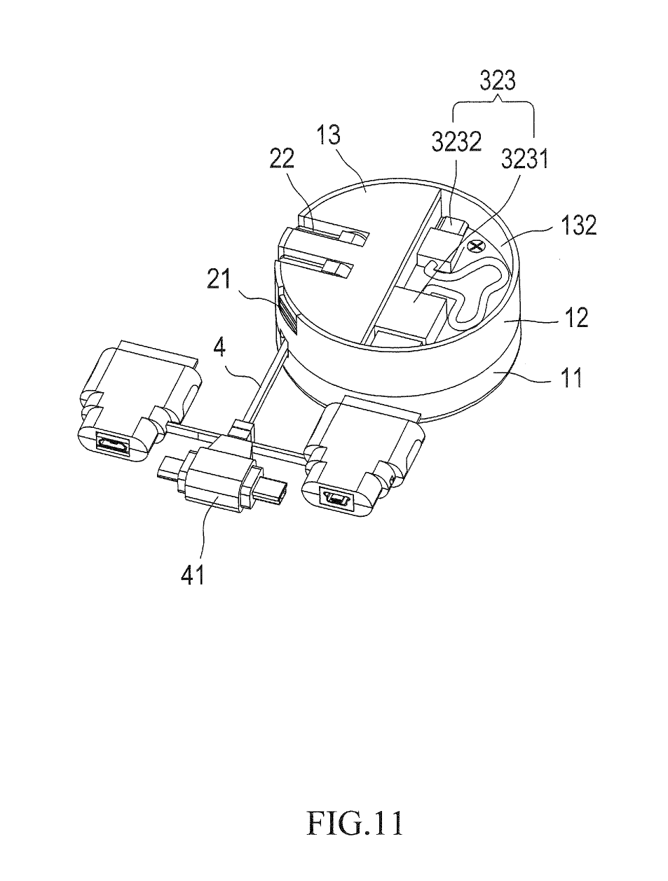

FIGS. 8-11 shows another partial number of components of the present invention. As shown, the components in the base seat 12 covered by the lower cover 13 generally include a power converting assembly 2, which includes a power converting module 24, an electrical port 21 fitted at a location corresponding to a cutout 123 defined on the base seat 12 for accessing port, and a power plug 22 fitted at a location corresponding to cutouts 128 defined on the base seat 12 for mating with slotted holes 131 defined on the lower cover 13. The electrical port 21 can be a USB connector. The power plug 22 can extend through the slotted hole 131 for external power connection. In particular, the power plug 22 includes a plug base 23, which is mounted and electrically connected with the electrical module 24, and two blades pivotably mounted on the plug base 23 so that the power plug 22 can be folded along the slotted holes 131. Further, a wall 127 is provided in the base seat 12, so that the lower cover 13 can be evenly mounted to the base seat 12.

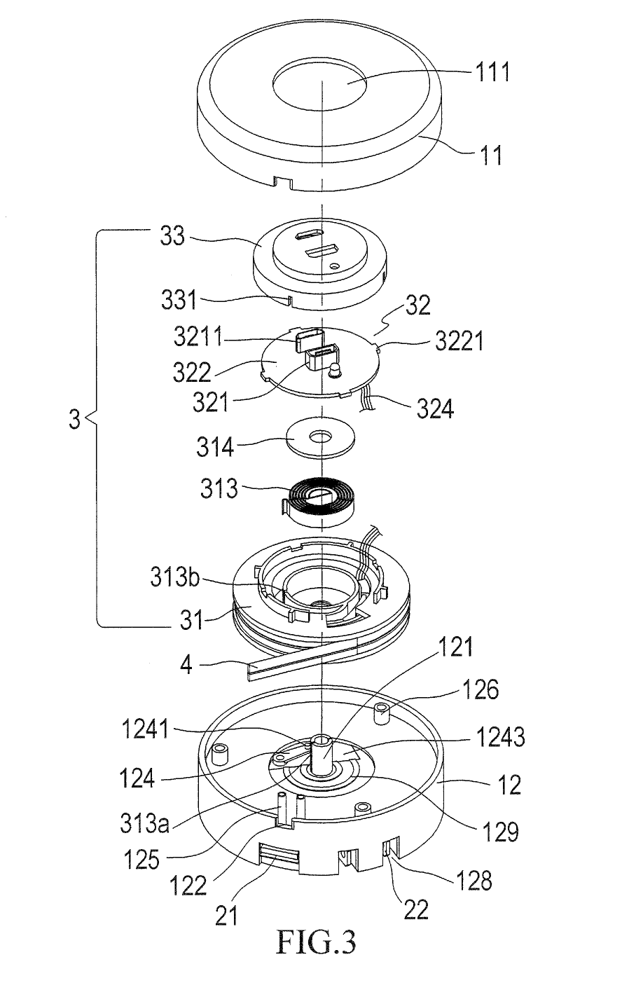

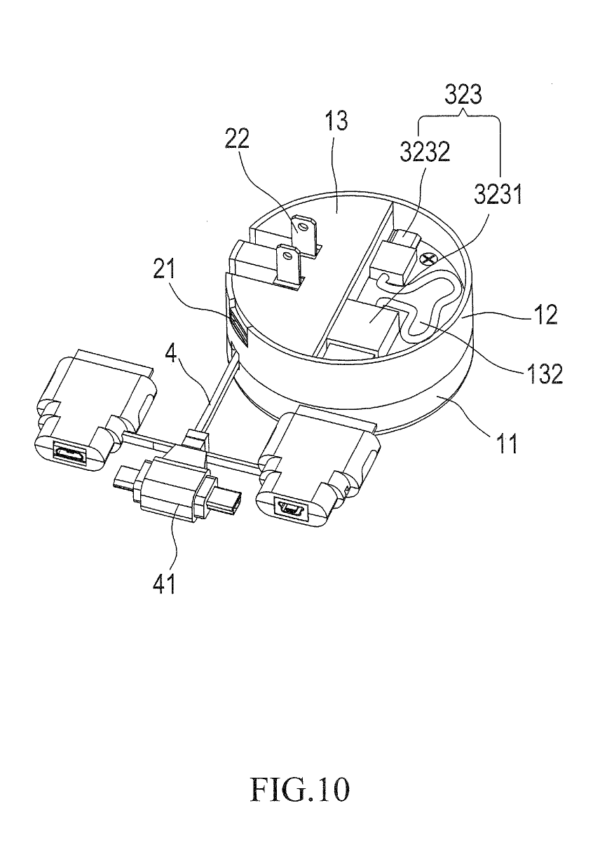

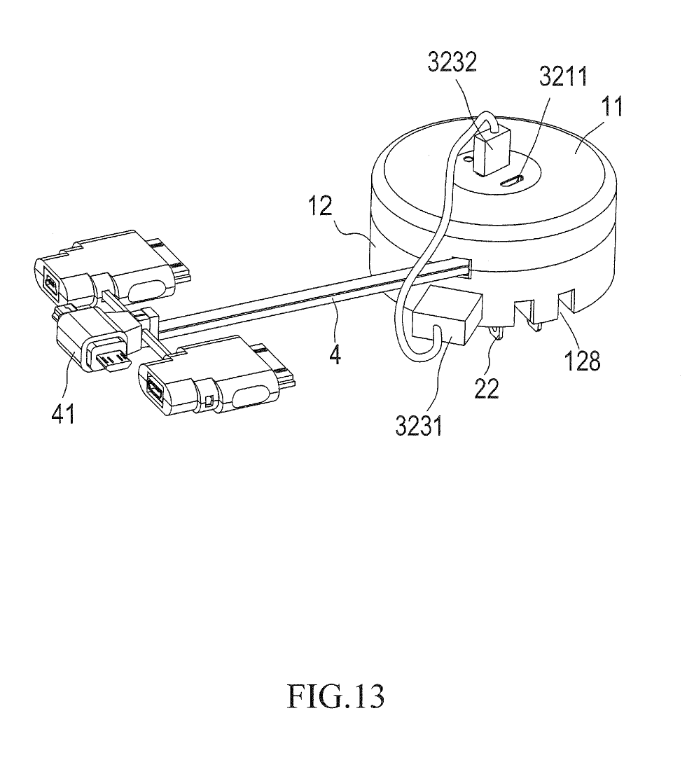

Referring to FIGS. 10 and 13, an adapting cable 323 can be accommodated in a recess 132 of the base seat 12. The adapting cable 323 can be employed to connect to the electrical port 21 of the power converting assembly 2 at a first end 3231 thereof and connected to the electrical port 321 of the electrical module 32 at a second end 3232 thereof so that the power converting assembly 2 is electrically connected with the electrical module 32. Each end of the adapting cable 323 can be a USB connector. Furthermore, a cable 324 is electrically connected to the cable 4 at one end thereof and is electrically connected to the circuit board 322 of the electrical module 32 at another end thereof (see FIG. 3); the power plug 22 of the power converting assembly 2 is electrically connected to the power converting module 24 of the power converting assembly 2, so that when the power plug 22 is inserted into a receptacle, the power converting module 24 can convert the external power to a suitable power for the connecting port assembly 41.

The cable 4 is electrically connected to the connecting port assembly 41, which includes connectors of various interfaces that can be selectively connected to a USB connector, a MINI USB connector, a MICRO USB connector, an HDMI connector, or a tablet computer charging connector. In addition to the connecting port assembly 41, the electrical ports 321, 3211 of the electrical module 32, the electrical port 21 of the power converting assembly 2, and each end of the adapting cable 323 can be adapted to connect to a USB connector, a MINI USB connector, a MICRO USB connector, an HDMI connector, or a tablet computer charging connector.

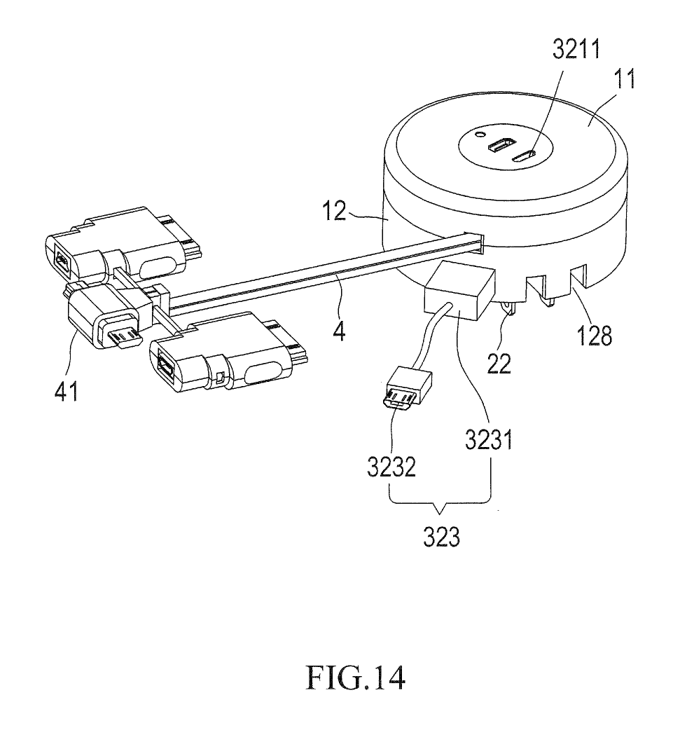

In view of the foregoing, when the cable 4 is pulled out of the housing 1, the reel 31 can be rotated via the rail 316 of the reel 31 and the tongue 124, whereby the elastic member 313 can be twisted to store energy for providing a restoring force for the cable 4, the boss 1241 of the tongue 124 can cooperate with the rail 316 of the reel 31 to fix the reel 31 at a position. For retracting the cable 4 into the housing 1, the cable 4 can be pulled again to cause the boss 1241 of the tongue 124 to escape from the fixing position, so that the cable 4 can retract into the housing 1 by the restoring force of the elastic member 313. Furthermore, when the power plug 22 is employed to connect to an external power supply, the power converting module 24 of the power converting assembly 2 can convert the external power to a suitable power to allow the electrical port 21 of the power converting assembly 2 to supply electrical power for various devices. The electrical port 3211 is electrically connected with the electrical port 321 via the circuit board 322 of the electrical module 32. Thus, after the adapting cable 323 is connected between the electrical port 21 and the electrical port 321, the electrical port 3211 can supply power as well. In such condition, the connecting port assembly 41 can also obtain the power converted from the power converting module 24 of the power converting assembly 2. Alternatively, as shown in FIG. 14, the first end 3231 of the adapting cable 323 can connect to the electrical port 21 of the power converting assembly 2 while the second end 3232 of the adapting cable 323 can be adapted to connect to a desired target for supplying power thereto.

When the device 100 is not employed to supply power, the device 100 can serve as an extension cable for conveying signal from the electrical ports 321, 3211 to the connecting port assembly 41.

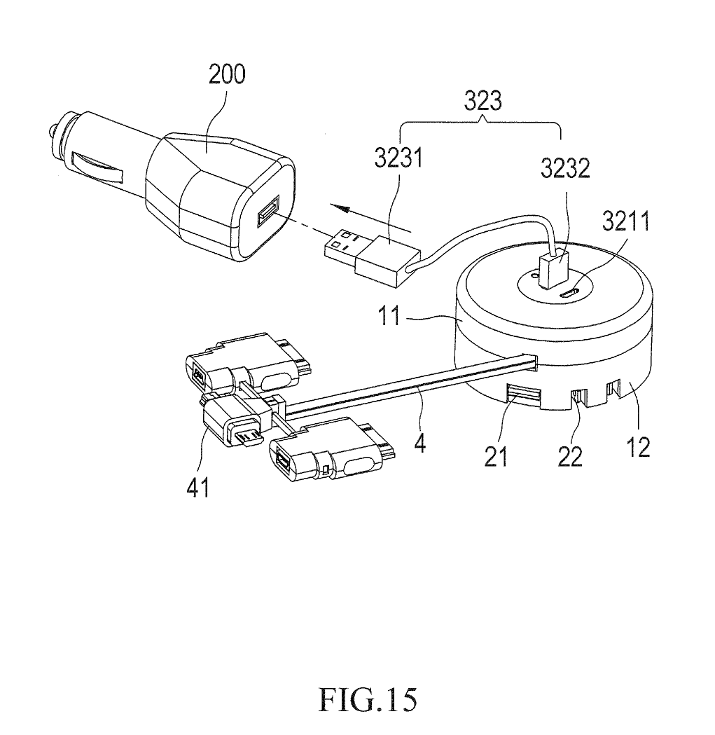

Referring to FIG. 15, the electrical port 321 of the electrical module 32 can be adapted to connect to a cigarette lighter for cars via an adapter 200 to allow the device 100 to obtain electrical power from the cars, which in turn supply mobile products with electrical power for charging batteries thereof or direct use.

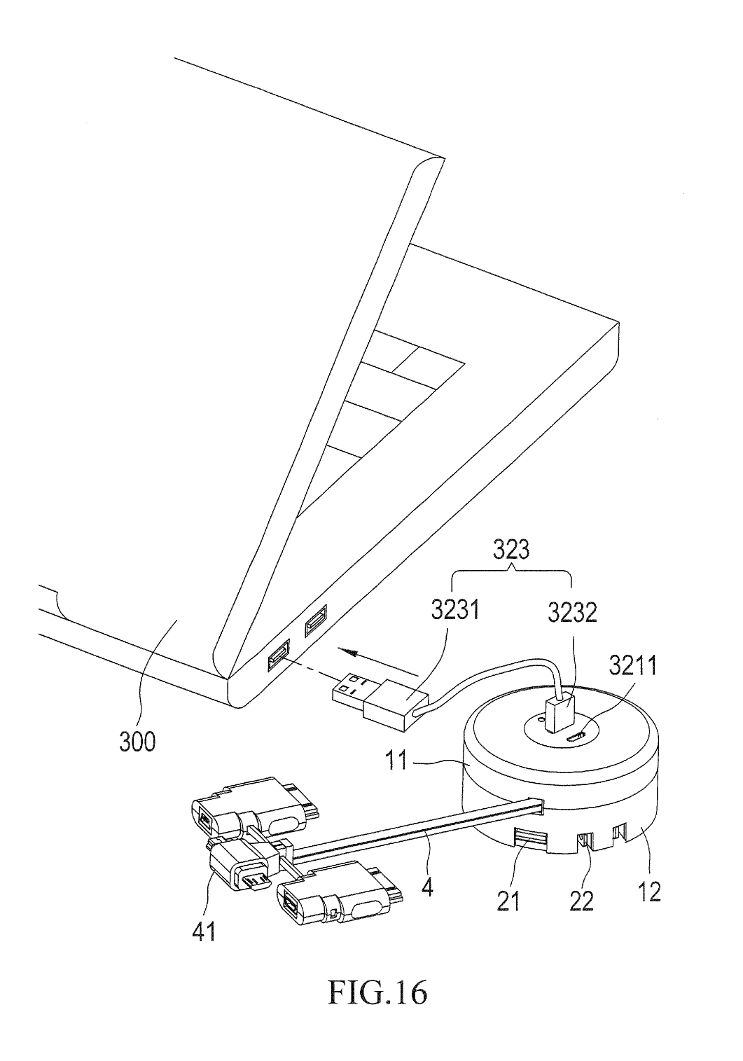

FIG. 16 illustrates an exemplary application of the present invention. As shown, the electrical port 321 of the electrical module 32 can connect to a USB connector of a notebook computer 300, and thus the connecting port assembly 41 can be employed to convey signal and supply power for various devices.

In light of the foregoing, the present invention can obtain various power sources to supply various devices, such as mobile phones or PDA or the like, for charging batteries thereof or direct use. Additionally, the present invention can serve as an extension cable for conveying signals between devices. More additionally, the present invention can be assembled in a compact form to facilitate carrying with the target devices.

Although the present invention has been described with a certain degree of particularity, it is understood that the present disclosure is made by way of example only and the combination and arrangement of parts may be resorted to without departing from the spirit and scope of the invention hereinafter claimed.

I claim:

1. A device for conveying signal and/or supplying power, comprising:
a housing including an upper cover, a base seat, and a lower cover, said upper cover and said lower cover being mounted to said base seat respectively at two sides of said base seat, said base seat being provided with a central axel and defining a cutout for cable exit and a cutout for accessing port, a tongue being pivotally mounted in said base seat, said upper cover defining at least one opening, said lower cover defining one or more slotted holes;
a power converting assembly mounted in said housing, said power converting assembly including a power converting module, an electrical port fitted at a location corresponding to said cutout for accessing port, and a power plug fitted at a location corresponding to said slotted holes, through which said power plug can extend for external power connection;
a reel assembly mounted in said housing, said reel assembly including a reel rotatably mounted with said central axle of said base seat via a through hole thereof, said reel defining an annular groove along a circumference thereof, said reel being provided with rails at a side thereof to cooperate with said tongue, said reel defining a cylindrical recess being coaxially therewith;
an elastic member disposed in said cylindrical recess of said reel, said elastic member having one end connected to said central axle of said base seat and another end connected to said reel;
an electrical module including at least one electrical port and a circuit board mounted on said reel, said electrical port of said electrical module being accessible through said opening of said upper cover; and
at least one cable being wound along said annular groove of said reel, and being electrically connected to said electrical module at one end thereof and being electrically connected to a connecting port assembly, through said cutout for cable exit defined on said base seat, at another end thereof.

2. The device of claim 1, wherein said reel assembly includes a protective cap mounted on said reel below said upper cover to be rotated together with said reel, said protective cap defining at least one slot at a portion being mated with said opening of said upper cover, said electrical port of said electrical module extending through said slot of said protective cap.

3. The device of claim 1, further comprising an adapting cable connected to said electrical port of said power converting assembly at one end thereof and connected to said electrical port of said electrical module at another end thereof so that said power converting assembly is electrically connected with said electrical module.

4. The device of claim 1, wherein two rolling means are mounted in said housing near said cutout for cable exit, said cable extending out of said housing through a gap between said two rolling means so as to facilitate pulling said cable.

5. The device of claim 1, wherein a partition plate is mounted on said reel between said electrical module and said elastic member for separating said electrical module from said elastic member to prevent friction therebetween.

6. The device of claim 1, wherein said power plug of said power converting assembly includes a plug base mounted and electrically connected with said electrical module and two blades pivotably mounted on said plug base so that said power plug can be folded along said slotted hole.

7. The device of claim 1, wherein said electrical port of said electrical module is adapted to connect to a cigarette lighter for cars or a USB port.

8. The device of claim 1, wherein said connecting port assembly is adapted to connect to a USB connector, a MINI USB connector, a MICRO USB connector, an HDMI connector, or a tablet computer charging connector.

9. The device of claim 1, wherein said electrical port of said power converting assembly is adapted to connect to a USB connector, a MINI USB connector, a MICRO USB connector, an HDMI connector, or a tablet computer charging connector.

10. The device of claim 1, wherein said electrical port of said electrical module is adapted to connect to a USB connector, a MINI USB connector, a MICRO USB connector, an HDMI connector, or a tablet computer charging connector.

11. The device of claim 1, wherein said upper cover is mounted to said base seat by at least one fastening member.

12. The device of claim 1, wherein a cylindrical wall is formed on said reel around said cylindrical recess, said cylindrical wall defining a plurality of notches thereon for engaging with projections formed on a periphery of said electrical module.

13. The device of claim 3, wherein said adapting cable having two ends each adapted to connect to a USB connector, a MINI USB connector, a MICRO USB connector, an HDMI connector, or a tablet computer charging connector.
